(19) United States
(12) Patent Application Publication
(10) Pub. No.: US 2024/0174838 A1
(43) Pub. Date: May 30, 2024

(54) SURFACE-TREATED INORGANIC POWDER, PRODUCTION METHOD THEREOF, AND RESIN COMPOSITION AND DISPERSION COMPRISING SAID SURFACE-TREATED INORGANIC POWDER

(71) Applicant: TOKUYAMA CORPORATION, Shuman-shi, Yamaguchi (JP)

(72) Inventors: Hiroaki TAIRA, Yamaguchi (JP); Hiromasa FUJIOKA, Yamaguchi (JP); Osamu TANAKA, Yamaguchi (JP); Teppei YAMADA, Yamaguchi (JP); Ayane NISHI, Yamaguchi (JP)

(21) Appl. No.: 18/281,918

(22) PCT Filed: Apr. 18, 2022
(86) PCT No.: PCT/JP2022/018000

§ 371 Date: Sep. 13, 2023

(30) Foreign Application Priority Data
Apr. 23, 2021 (JP) 2021-073614

(51) Int. Cl. C08K 9/06; C09C 1/30; C09C 1/36; C09C 3/00; C09C 3/12; H01L 23/29

(52) U.S. Cl. CPC C08K 9/06; C09C 1/3081; C09C 1/36; C09C 3/003; C09C 3/12; C01P 2002/86; C01P 2002/89; C01P 2004/32; C01P 2006/12; C01P 2006/80; H01L 23/295

(57) ABSTRACT

Provided are a surface-treated inorganic powder, which satisfies the following expression (1) and the following expression (2), and a method of producing the same, and a dispersion and a resin composition each containing the surface-treated inorganic powder: ⋅Expression (1) 3.0≤D1≤50.0; ⋅Expression (2) 1.00≤D1/D2<1.10, in the expression (1) and the expression (2), D1 represents a presence amount (μmol/m²) of double bonds contained in the surface-treated inorganic powder, and D2 represents a presence amount (μmol/m²) of double bonds contained in a washed powder, wherein the washed powder is a powder obtained by subjecting the surface-treated inorganic powder to predetermined washing treatments.

### CROSS REFERENCE TO RELATED APPLICATIONS

This application is a 371 U.S. National Phase of International Application No. PCT/JP2022/018000, filed on Apr. 18, 2022, which claims priority to Japanese Patent Application No. 2021-073614, filed Apr. 23, 2021. The entire disclosures of the above applications are incorporated herein by reference.

### TECHNICAL FIELD

The present invention relates to a surface-treated inorganic powder and a method of producing the same, and to a dispersion and a resin composition each containing the surface-treated inorganic powder.

### BACKGROUND ART

A compound having a polymerizable double bond, such as a photocurable resin or a thermosetting resin, is widely utilized for an adhesive, a coating material, and the like. When the compound having a polymerizable double bond is used as an adhesive for an electronic material such as a semiconductor encapsulation material, there is often used a technology involving adding an inorganic powder to the compound to improve its adhesive strength or reduce its thermal expansion coefficient. In addition, when the compound having a polymerizable double bond is used as a coating material typified by a hard coat or the like, the inorganic powder is added to the compound to achieve an improvement in surface hardness or an improvement in slipperiness. In those applications, there have been reported many technologies for introducing a functional group into a surface of the inorganic powder with a silane coupling agent in order to improve its performance. For example, introduction of a silane coupling agent having a (meth)acryloyl group into the surface of the inorganic powder has also been investigated for the purpose of forming strong resin-particle bonding between a photocurable resin, such as acrylic resin acrylate, epoxy acrylate, or urethane acrylate, and the inorganic powder.

In this connection, as a method of introducing the silane coupling agent into the surface of the inorganic powder, in JP 2014-133697 A, there is a disclosure of a method of subjecting an inorganic powder to surface treatment in a liquid medium containing water (so-called wet process). However, in the surface treatment method described in JP 2014-133697 A, when the surface treatment of the inorganic powder with the silane coupling agent is performed at high temperature, particles aggregate. Accordingly, this surface treatment method has had a problem in that treatment efficiency is low because the surface treatment of inorganic particles with the silane coupling agent needs to be performed at a low temperature for a long period of time (e.g., at 40° C. for 72 hours) to suppress the aggregation of the particles. In view of this, in order to introduce the silane coupling agent into the surface of the inorganic powder with high treatment efficiency, there has also been developed a method involving subjecting inorganic particles to surface treatment by a dry process under the conditions of a high temperature and a short period of time (a temperature equal to or higher than the boiling point of water, for example, from 120° C. to 140° C., and 5 hours.) (see, for example, JP 2016-052953 A).

Meanwhile, the inventors of the present invention have investigated the mechanical strength of a cured body obtained by curing a resin composition containing: an inorganic powder (surface-treated inorganic powder) obtained by performing surface treatment by the related-art dry process exemplified in JP 2016-052953 A and the like under the conditions of a high temperature and a short period of time; and a resin having a polymerizable double bond (hereinafter sometimes referred to as “curable resin”). As a result, it has been revealed that the mechanical strength of the obtained cured body cannot necessarily be said to be sufficient.

The present invention has been made in view of the above-mentioned circumstances, and an object of the present invention is to provide a surface-treated inorganic powder capable of providing a cured body excellent in mechanical strength when blended into a resin composition and a method of producing the same, and a dispersion and a resin composition each containing the surface-treated inorganic powder.

### SUMMARY

The above-mentioned object is achieved by the present invention to be described below. That is, according to one embodiment of the present invention, there is provided a surface-treated inorganic powder, which satisfies the following expression (1) and the following expression (2):

3.0≤D1≤50.0 Expression (1)

1.00≤D1/D2<1.10 Expression (2)

in the expression (1) and the expression (2), D1 represents a presence amount (μmol/m²) of double bonds contained in the surface-treated inorganic powder, and D2 represents a presence amount (μmol/m²) of double bonds contained in a washed powder, wherein the washed powder is a powder obtained by sequentially subjecting the surface-treated inorganic powder to treatments shown in the following <1> to <3>:
<1> 50 mL of methanol and 10 g of the surface-treated inorganic powder are mixed to provide a dispersion liquid;
<2> the dispersion liquid is treated with an ultrasonic disperser at an output of 40 W for 20 minutes to provide a slurry; and
<3> solid matter obtained by centrifuging the slurry and removing a supernatant is dried under reduced pressure at a pressure of 0.1 MPa and a temperature of 50° C. for a treatment time of 12 hours to provide the washed powder.

According to one embodiment of the present invention, there is provided a method of producing a surface-treated inorganic powder, including: a raw-material-for-surface-treatment preparation step of mixing: 100 parts by mass of a silane coupling agent having a (meth)acryloyl group; 0.3 part by mass to 50 parts by mass of a polymerization inhibitor; and an inorganic powder, to thereby prepare a raw material for surface treatment; a surface treatment step of heating the raw material for surface treatment to 110° C. or more by a dry process, to thereby prepare a surface-treated raw material containing the inorganic powder surface-treated with the silane coupling agent; and a washing step of washing the surface-treated raw material.

According to one embodiment of the present invention, there is provided a dispersion, including the surface-treated inorganic powder according to the embodiment of the present invention.

According to one embodiment of the present invention, there is provided a resin composition, including the surface-treated inorganic powder according to the embodiment of the present invention.

### Advantageous Effects of Invention

According to the present invention, the surface-treated inorganic powder capable of providing a cured body excellent in mechanical strength when blended into a resin composition and the method of producing the same, and the dispersion and the resin composition each containing the surface-treated inorganic powder can be provided.

### DETAILED DESCRIPTION OF EMBODIMENTS

### <Surface-Treated Inorganic Powder, Dispersion, and Resin Composition>

A surface-treated inorganic powder according to this embodiment satisfies the following expression (1) and the following expression (2):

3.0≤D1≤50.0 Expression (1)

1.00≤D1/D2<1.10 Expression (2)

in the expression (1) and the expression (2), D1 represents a presence amount (μmol/m²) of double bonds contained in the surface-treated inorganic powder, and D2 represents a presence amount (μmol/m²) of double bonds contained in a washed powder, wherein the washed powder is a powder obtained by sequentially subjecting the surface-treated inorganic powder to treatments shown in the following <1> to <3>:
<1> 50 mL of methanol and 10 g of the surface-treated inorganic powder are mixed to provide a dispersion liquid;
<2> the dispersion liquid is treated with an ultrasonic disperser at an output of 40 W for 20 minutes to provide a slurry; and
<3> solid matter obtained by centrifuging the slurry and removing a supernatant is dried under reduced pressure at a pressure of 0.1 MPa and a temperature of 50° C. for a treatment time of 12 hours to provide the washed powder.

The surface-treated inorganic powder according to this embodiment includes: an inorganic powder; and a surface treatment agent, which is present on a surface of the inorganic powder, and contains a carbon atom. As the surface treatment agent, there is used a silane coupling agent having a reactive (polymerizable) double bond derived from a functional group, such as a (meth)acryloyl group or a vinyl group. In addition, in the description of the present application, the “double bond” contained in each of the surface-treated inorganic powder and the washed powder means a reactive (polymerizable) double bond (C═C) formed by bonding between constituent carbon atoms of the surface treatment agent. The silane coupling agent is particularly suitably a silane coupling agent having a (meth)acryloyl group.

In investigating the above-mentioned surface-treated inorganic powder according to this embodiment and a method of producing the same, first, the inventors of the present invention have investigated the reason why the mechanical strength of a cured body obtained by curing a resin composition having blended thereinto a surface-treated inorganic powder obtained by performing surface treatment by the related-art dry process under the conditions of a high temperature and a short period of time becomes insufficient. As a result, the inventors of the present invention have obtained findings described below. First, it is known that (meth)acryloyl groups are polymerized by heat. Accordingly, when surface treatment is performed at high temperature, the polymerization reaction of the (meth)acryloyl groups progresses, and silane coupling agents present on the surface of the inorganic powder are bonded to each other. It is conceived that, as a result, along with the progress of the surface treatment, the amount of double bonds derived from the (meth)acryloyl groups decreases or approaches zero, and the polymerization reaction of the silane coupling agent progresses between individual constituent particles of the inorganic powder to form aggregated particles. Accordingly, in a resin composition having blended thereinto the surface-treated inorganic powder that has undergone those phenomena in the course of the surface treatment, covalent bonds are not sufficiently formed between the silane coupling agent contained in the surface-treated inorganic powder and a curable resin at the time of the curing of the resin composition. In addition, presumably as a result, the mechanical strength of the cured body becomes insufficient.

Meanwhile, when the surface treatment is performed at high temperature, a measure for suppressing the decrease in double bonds along with the progress of the surface treatment is, for example, to perform the surface treatment in a short period of time as exemplified in JP 2016-052953 A. (1) However, when the surface treatment time is short, the silane coupling agent applied to the surface of the inorganic powder is liable to remain while being unable to chemically react with the surface of the inorganic powder at the time of the surface treatment. In addition, in order to perform the surface treatment so as to reliably cover the entire surface of the inorganic powder with the silane coupling agent, it is generally suitable that the surface treatment be performed using the silane coupling agent in an excess amount with respect to the number of reaction sites present on the surface of the inorganic powder. (2) In this case, however, there occurs a silane coupling agent that cannot chemically react with a reaction site present on the surface of the inorganic powder at the time of the surface treatment. In addition, the silane coupling agent that has failed to chemically react with the surface of the inorganic powder described in (1) and/or (2) above is merely physically adsorbed onto the surface of the inorganic powder, and hence is presumed not to contribute to the formation of a chemical bond required for improving the mechanical strength of the cured body (covalent bond between the surface of the inorganic powder and the curable resin via the silane coupling agent).

In view of the foregoing, the inventors of the present invention have found the surface-treated inorganic powder according to this embodiment and the method of producing the same on the basis of the above-mentioned findings.

Herein, the presence amount D1 (μmol/m²) of double bonds contained in the surface-treated inorganic powder according to this embodiment is a value calculated by dividing the amount of double bonds per unit mass (μmol/g) of the surface-treated inorganic powder, which is measured by Wijs' method, by the specific surface area (m²/g) of the inorganic powder. In addition, the presence amount D2 (μmol/m²) of double bonds contained in the washed powder is a value calculated by dividing the amount of double bonds per unit mass (μmol/g) of the washed powder, which is measured by Wijs' method, by the specific surface area (m²/g) of the inorganic powder. The specific surface area of the inorganic powder is a value measured by a BET one-point method.

The presence amount D1 of double bonds needs to be 3.0 μmol/m² or more from the viewpoint of obtaining a cured body having excellent mechanical strength, and is preferably 3.5 μmol/m² or more, more preferably 4.0 μmol/m² or more. Meanwhile, when the presence amount D1 of double bonds is excessively large, there is an increased risk in that aggregated particles may be formed at the time of the surface treatment. Then, the formed aggregated particles result in a reduction in strength of the cured body. Accordingly, the presence amount D1 of double bonds needs to be 50.0 μmol/m² or less, and is preferably 40.0 μmol/m² or less, more preferably 30.0 μmol/m² or less.

In addition, the ratio (D1/D2) between the presence amount D1 (μmol/m²) of double bonds contained in the surface-treated inorganic powder and the presence amount D2 (μmol/m²) of double bonds contained in the washed powder needs to be 1.00 or more and less than 1.10, and is more preferably 1.00 or more and 1.05 or less, still more preferably 1.00 or more and 1.02 or less. Herein, the washed powder is a powder obtained by subjecting the surface-treated inorganic powder to extremely powerful washing and centrifugation treatments shown in <1> to <3> above. Accordingly, it is presumed that the silane coupling agent contained in the washed powder is equivalent to a remainder obtained by substantially excluding the silane coupling agent physically adsorbed onto the inorganic powder from the silane coupling agent contained in the surface-treated inorganic powder. In other words, it is presumed that the silane coupling agent contained in the washed powder is substantially equivalent to the silane coupling agent chemically adsorbed onto the inorganic powder. Accordingly, it is conceived that the ratio D1/D2 means a parameter approximately identical or similar to “(presence amount of chemically adsorbed silane coupling agent+presence amount of physically adsorbed silane coupling agent)/presence amount of chemically adsorbed silane coupling agent.” Accordingly, when the value of the ratio D1/D2 is excessively large, the ratio of the physically adsorbed silane coupling agent in the silane coupling agent contained in the surface-treated inorganic powder becomes excessively large, in other words, the ratio of the silane coupling agent that does not contribute to the formation of a covalent bond between the surface-treated inorganic powder and the curable resin required for improving the mechanical strength of the cured body becomes excessively large. However, in the surface-treated inorganic powder according to this embodiment, the ratio D1/D2 is set to less than 1.10, and hence a cured body having excellent mechanical strength can be obtained.

The double bonds contained in the surface-treated inorganic powder according to this embodiment are each a reactive double bond contained in the silane coupling agent used at the time of the surface treatment of the inorganic powder (double bond derived from a (meth)acryloyl group or the like). Herein, any silane coupling agent having in the molecule a functional group containing a reactive double bond may be used without any particular limitation as the silane coupling agent to be used for the surface treatment, but a silane coupling agent having a (meth)acryloyl group is particularly suitably used. As the silane coupling agent having a (meth)acryloyl group, any of an aliphatic silane coupling agent and an aromatic silane coupling agent may be used. Specifically, 3-methacryloxypropylmethyldimethoxysilane, 3-methacryloxypropyltrimethoxysilane (MPTS), 3-methacryloxypropylmethyldiethoxysilane, 3-methacryloxypropyltriethoxysilane, 8-methacryloxyoctyltrimethoxysilane, 3-acryloxypropyltrimethoxysilane (APTS), an alkoxyoligomer-type coupling agent having introduced thereinto an acrylic group (e.g., KR-513 manufactured by Shin-Etsu Chemical Co., Ltd.), and a polyfunctional group-type silane coupling agent (e.g., X-12-1048 manufactured by Shin-Etsu Chemical Co., Ltd.) may be suitably used.

In addition, in the surface-treated inorganic powder according to this embodiment, the carbon content per unit surface area of the surface-treated inorganic powder preferably falls within the range of from 10 μmol/m² to 200 μmol/m². Herein, the carbon content (μmol/m²) is a value calculated by dividing the carbon content per unit mass (μmol/g) of the surface-treated inorganic powder, which is determined by a combustion oxidation method, by the specific surface area (m²/g) of the inorganic powder. The specific surface area of the inorganic powder is a value measured by the BET one-point method. In order to avoid the formation of aggregated particles at the time of the surface treatment as much as possible, and to achieve a further improvement in mechanical strength of the cured body, the carbon content (μmol/m²) has an upper limit value of preferably 200 μmol/m² or less, more preferably 150 μmol/m² or less, most preferably 130 μmol/m² or less, and has a lower limit value of preferably 10 μmol/m² or more, more preferably 20 μmol/m² or more, most preferably 30 μmol/m² or more.

Herein, the carbon content (μmol/m²) may be adjusted on the basis of the amount of the silane coupling agent to be used for the surface treatment and the amount of moisture present in the system at the time of the surface treatment. In general, adsorbed water present on the surface of the inorganic powder reacts with a hydrolyzable functional group of the silane coupling agent to generate a silanol group. In addition, for example, when the inorganic powder is silica particles, a silanol group on a silica surface and a silanol group derived from the silane coupling agent condense, and thus the silane coupling agent is bonded to the silica surface. Accordingly, the amount of the silane coupling agent to be bonded to the silica surface (i.e., carbon content) can be increased by increasing the amount of the silane coupling agent up to an amount capable of reacting with all silanol groups on the silica surface. However, when the amount of the silane coupling agent to be used for the surface treatment exceeds a certain value, the carbon content is saturated. In view of this, the amount of moisture present in the system is controlled through, for example, supplemental addition of water vapor into the system to cause moisture to adsorb or adhere onto the silica surface, and a larger amount of the silane coupling agent than normal is used. Thus, a larger amount of the silane coupling agent than normal can be allowed to react with the silica surface as well. However, when the amount of moisture that has adsorbed or adhered onto the silica surface is large, aggregation between the inorganic powders, and condensation between the silane coupling agents and the crosslinking reaction between the inorganic particles occur to form coarse particles in some cases. Accordingly, when the carbon content is adjusted on the basis of the amount of moisture present in the system, the adjustment is preferably performed within a range in which the coarse particles are not formed.

In addition, it is also possible to reduce the amount of the silane coupling agent to be bonded to the surface of the inorganic powder by reducing the amount of the silane coupling agent to be used for the surface treatment. In this case, however, the mechanical strength of the cured body obtained by curing the resin composition having blended thereinto the surface-treated inorganic powder is liable to become insufficient. The carbon content depends on the number of moles of the silane coupling agent to be bonded per unit surface area and the number of constituent carbon atoms of the molecule of the silane coupling agent. Accordingly, when the number of moles of the silane coupling agent to be bonded per unit surface area is the same, a silane coupling agent having a larger number of carbon atoms in the molecule has a larger value for the carbon content. As the number of carbon atoms in the molecule increases, there is a higher increasing effect on the mechanical strength of the cured body based on the effect of a hydrophobic interaction between the curable resin contained in the resin composition and the silane coupling agent. Accordingly, it is preferred that, as well as the presence amount of (meth)acryloyl groups, i.e., the presence amount of double bonds present per unit surface area, the carbon content per unit surface area be high. Herein, the amount of moisture present in the system may be measured by calculating a difference between the total amount of moisture (concentration×integrated flow volume) contained in a gas supplied to a reaction vessel to be used for the surface treatment of the inorganic powder and the total amount of moisture (concentration×integrated flow volume) contained in a gas purged (discharged) from the reaction vessel.

When the inorganic powder is subjected to the surface treatment with the silane coupling agent, as the number of molecules of the silane coupling agent to be bonded per unit surface area increases, the number of (meth)acryloyl groups to be introduced into the surface of the inorganic powder increases. However, when the number of (meth)acryloyl groups to be introduced into the surface of the inorganic powder is excessively large, aggregation caused by the crosslinking reaction between the inorganic particles is liable to occur. In addition, when the aggregation occurs, there is a fear in that a defect may occur in an application in which coarse particles are undesirable, for example, an application such as a surface coating agent, a semiconductor encapsulation material, or a liquid crystal sealant. Accordingly, the amount (g) of the silane coupling agent to be bonded to the inorganic powder is preferably from about 0.5 times to about 10 times, more preferably from about 0.5 times to about 5 times as large as the theoretical bonded amount (g). The “theoretical bonded amount (g)” in this case is expressed by the following equation, and the amount of the silane coupling agent needs to be controlled depending on the specific surface area of the inorganic powder to be used.

Theoretical bonded amount (g)=(amount of inorganic powder to be used (g)×specific surface area of inorganic powder (m²/g))/minimum coverage area of silane coupling agent (m²/g)

A value disclosed for a commercially available silane coupling agent by its manufacturer is used as the minimum coverage area. In actuality, it may also be possible to bond the silane coupling agent in an amount more than 1 times as large as the theoretical bonded amount depending on the surface properties of the inorganic powder to be used and the amount of adsorbed water present on the surface of the inorganic powder at the time of the reaction.

Further, in the surface-treated inorganic powder according to this embodiment, a difference (C1-C2) between a carbon amount C1 (ppm) of the surface-treated inorganic powder and a carbon amount C2 (ppm) of the washed powder is preferably less than 100 ppm, more preferably 80 ppm or less, still more preferably 50 ppm or less. Here, a larger difference (C1-C2) between the carbon amounts means that larger amounts of carbon compounds, such as the physically adsorbed silane coupling agent and a polymerization inhibitor, remain in the surface-treated inorganic powder. In addition, those components make no contribution to, or inhibit, the formation of a chemical bond required for improving the mechanical strength of the cured body (covalent bond between the surface of the inorganic powder and the curable resin via the silane coupling agent). Accordingly, when the difference (C1-C2) between the carbon amounts is set to less than 100 ppm, it becomes easy to further improve the mechanical strength of the cured body. The carbon amount of each of the surface-treated inorganic powder and the washed powder is measured by the combustion oxidation method.

In addition, when a silane coupling agent having a (meth)acryloyl group is used as the surface treatment agent, it is preferred that, in a ¹³C CP MAS NMR spectrum of the surface-treated inorganic powder according to this embodiment, an intensity ratio (M/N) between a peak height (M) within the range of from 120 ppm to 150 ppm and a peak height (N) within the range of from 0 ppm to +10 ppm be from 0.5 to 5. In the ¹³C CP MAS NMR spectrum, a peak attributed to the double-bonded carbon of the (meth)acryloyl group is observed in the range of from 120 ppm to 150 ppm, and a peak attributed to a carbon atom next to a Si atom of the silane coupling agent is observed in the range of from 0 ppm to +10 ppm. A larger value of the intensity ratio (M/N) means that double bonds introduced into the surface of the inorganic powder by the silane coupling agent are present (i.e., remain) in a large number. Accordingly, when the intensity ratio (M/N) is set to 0.5 or more, it becomes easy to further improve the mechanical strength of the cured body. The intensity ratio (M/N) is more preferably 0.8 or more, most preferably 1.0 or more. Meanwhile, when the value of the intensity ratio (M/N) is excessively large, a larger number of double bonds are present with respect to one silicon atom derived from the silane coupling agent, and hence there is a risk in that aggregates (coarse particles) may be formed at the time of the surface treatment. Accordingly, the intensity ratio (M/N) is preferably 5.0 or less, more preferably 4.0 or less, most preferably 3.5 or less.

In addition, the surface-treated inorganic powder according to this embodiment preferably has a sphericity of primary particles of 0.80 or more. When the sphericity is low, a mixed composition obtained by mixing the surface-treated inorganic powder with other components such as a curable resin is liable to be reduced in fluidity and increased in viscosity. Accordingly, the sphericity is preferably 0.80 or more, more preferably 0.85 or more, most preferably 0.90 or more.

Further, a powder formed of a known inorganic material may be appropriately utilized as the inorganic powder for forming the surface-treated inorganic powder according to this embodiment, and for example, silica, alumina, zirconia, titania, or a composite oxide containing silica as a main component may be used. In addition, the composite oxide containing silica as a main component preferably contains a first component formed of silica and a second component formed of at least one kind selected from the group consisting of: titania; zirconia; and alumina. In this case, it is more preferred that the content ratio of the first component in the composite oxide be 60 mol % or more and less than 100 mol %. The inorganic powder is preferably made up of spherical particles, and from the viewpoint that the spherical particles are easily obtained, the inorganic powder is suitably formed of silica, alumina, or the above-mentioned composite oxide. In addition, when the inorganic powder is formed of silica, its origin is not particularly limited, and natural silica, synthetic silica, or the like may be suitably used. Of those, synthetic silica is preferred in that high-purity silica is obtained. A production process for the synthetic silica is not limited, and dry silica (flame process silica), such as fumed silica or molten silica, or wet process silica, such as gel process silica, precipitated silica, or sol-gel process silica, may be suitably used. Of those, dry silica or sol-gel process silica is particularly preferred for reasons, such as containing little metal impurities and providing a spherical inorganic powder.

A method of producing the composite oxide is not particularly limited, but from the viewpoint of obtaining a homogeneous and spherical composite oxide, it is preferred to use a method (dry process) of obtaining the composite oxide by introducing a plurality of organometal compounds and a silica source into a flame, or a method (sol-gel process) of obtaining the composite oxide by a sol-gel process using a plurality of organometal compounds and an organosilicon compound such as an alkoxysilane. The average particle diameter of each of the inorganic powder and the surface-treated inorganic powder produced using the inorganic powder is not particularly limited. However, when the resin composition having blended thereinto the surface-treated inorganic powder according to this embodiment is used as an encapsulation material for an electronic material, or as a film coating agent, the lower limit of the average particle diameter is preferably 0.05 μm or more, particularly preferably 0.08 μm or more. In addition, the upper limit of the average particle diameter is preferably 50 μm or less, more preferably 40 μm or less, most preferably 30 μm or less.

The width of the particle diameter distribution of each of the inorganic powder and the surface-treated inorganic powder produced using the inorganic powder is not particularly limited, and any one of the following may be adopted: a powder having high monodispersity such that its coefficient of variation (CV) in particle diameter is less than 30%; or a powder having a relatively wide distribution such that its coefficient of variation in particle diameter is 30% or more. In addition, the particle diameter distribution may be such a multimodal distribution as to have a plurality of maxima, and only needs to be appropriately selected in accordance with the intended use of the surface-treated inorganic powder according to this embodiment.

When the surface-treated inorganic powder according to this embodiment is utilized in an application in which contamination with coarse particles is unpreferred, such as a semiconductor encapsulation material or a liquid crystal sealant, the maximum particle diameter of each of the inorganic powder and the surface-treated inorganic powder produced using the inorganic powder is preferably 10 or less times, preferably 7 or less times, still more preferably 5 or less times as large as the average particle diameter. Further, in the surface-treated inorganic powder according to this embodiment, the content of coarse particles each having a particle diameter 5 or more times as large as the average particle diameter is preferably less than 10 ppm. If the content of the coarse particles is 10 ppm or more, when the resin composition having blended thereinto the surface-treated inorganic powder according to this embodiment is used in an application in which a distance between bonding surfaces is narrow like a semiconductor encapsulation material, a problem such as a failure to keep the distance between bonding surfaces at a desired distance occurs in some cases. In the description of the present application, the term “coarse particles” refers to particles each having a particle diameter 5 or more times as large as the average particle diameter of the powder (surface-treated inorganic powder or inorganic powder).

The surface-treated inorganic powder according to this embodiment preferably contains no polymerization inhibitor at all, but contains a slight amount of a polymerization inhibitor in some cases depending on a production method adopted, as in the method of producing the surface-treated inorganic powder according to this embodiment to be described later. In such cases, the content of the polymerization inhibitor in the surface-treated inorganic powder according to this embodiment is preferably less than 50 ppm, more preferably less than 10 ppm.

The surface-treated inorganic powder according to this embodiment may be generally utilized as a dispersion by being dispersed in some medium. The medium for forming the dispersion is not particularly limited, and examples thereof include: a curable resin; a resin other than the curable resin; a solvent; and a mixture of two or more kinds thereof in combination. In addition, the surface-treated inorganic powder according to this embodiment is suitably utilized as a resin composition by being dispersed and incorporated into a curable resin. In this case, a known photocurable resin or thermosetting resin having a polymerizable double bond may be utilized as the curable resin. A known curable resin may be utilized as such curable resin as long as the curable resin has a functional group capable of reacting with a double bond contained in a functional group such as a (meth)acryloyl group contained in the silane coupling agent. Suitable examples of the curable resin may include: compounds each having a (meth)acryloyl group, such as pentaerythritol triacrylate, pentaerythritol tetraacrylate, dipropylene glycol diacrylate, methyl methacrylate, ethyl methacrylate, butyl methacrylate, methoxyethyl acrylate, methoxyethyl methacrylate, compounds each having a such as hydroxyethyl methacrylate; (meth)acryloyl group, compounds each having a (meth)acryloyl group and a glycidyl group in the molecule, such as glycidyl acrylate, glycidyl methacrylate, bisphenol A-monoglycidyl ether-methacrylate, and 4-glycidyloxybutyl methacrylate; and compounds each having a vinyl group, such as divinylbenzene, styrene, and vinyl acetate. The blending amount of the surface-treated inorganic powder contained in the resin composition may be appropriately selected in accordance with applications of the resin composition, but may be set to, for example, from 10 mass % to 90 mass %.

### <Method of Producing Surface-Treated Inorganic Powder>

When the surface-treated inorganic powder according to this embodiment is produced, although its production method is not particularly limited, a production method described below is suitable. That is, a method of producing the surface-treated inorganic powder according to this embodiment preferably includes: a raw-material-for-surface-treatment preparation step of mixing: 100 parts by mass of a silane coupling agent having a (meth)acryloyl group; 0.3 part by mass to 50 parts by mass of a polymerization inhibitor; and an inorganic powder, to thereby prepare a raw material for surface treatment; a surface treatment step of heating the raw material for surface treatment to 110° C. or more by a dry process, to thereby prepare a surface-treated raw material containing the inorganic powder surface-treated with the silane coupling agent; and a washing step of washing the surface-treated raw material. In addition, the method of producing the surface-treated inorganic powder according to this embodiment may further include a step other than the raw-material-for-surface-treatment preparation step, the surface treatment step, and the washing step as required. Details about each step are described below.

### (Raw-Material-for-Surface-Treatment Preparation Step and Surface Treatment Step (Dry Process))

In the raw-material-for-surface-treatment preparation step, 100 parts by mass of a silane coupling agent having a (meth)acryloyl group, 0.3 part by mass to 50 parts by mass of a polymerization inhibitor, and an inorganic powder are mixed to prepare a raw material for surface treatment. In this case, the raw material for surface treatment is preferably prepared by preparing a surface treatment agent mixture, which is obtained by mixing the silane coupling agent and the polymerization inhibitor in advance, and then mixing the surface treatment agent mixture and the inorganic powder. When the polymerization inhibitor and the silane coupling agent are separately mixed with the inorganic powder, there is a risk in that the polymerization inhibitor may be localized to make a polymerization-preventing effect on the silane coupling agent insufficient in the surface treatment step serving as a subsequent step. In the preparation of the surface treatment agent mixture, when the polymerization inhibitor and the silane coupling agent cannot be uniformly mixed, a solution obtained by dissolving the polymerization inhibitor in a small amount of an organic solvent may be prepared in advance, followed by mixing of the solution with the silane coupling agent. From the viewpoint of the ease of solvent removal in the case of removing the organic solvent from the surface-treated raw material obtained through surface treatment, the boiling point of the organic solvent to be used for the preparation of the solution is preferably 150° C. or less.

The usage amount of the silane coupling agent to be used for the preparation of the raw material for surface treatment only needs to be set with reference to a theoretical bonded amount obtained in consideration of the minimum coverage area of the silane coupling agent and the specific surface area and amount of the inorganic powder, and is an amount preferably 10 or less times, more preferably 5 or less times as large as the theoretical bonded amount. When the usage amount of the silane coupling agent is more than 10 times as large as the theoretical bonded amount, aggregates may occur in the subsequent step (surface treatment step).

A known substance may be used as the polymerization inhibitor to be used for the preparation of the raw material for surface treatment. Suitable examples thereof include: phenols, such as 4-tert-butylcatechol, dibutylhydroxytoluene (BHT), p-methoxyphenol, hydroquinone, tert-butylhydroquinone (TBHQ), and methylhydroquinone; amines, such as phenothiazine, 4-hydroxydiphenylamine, diphenylamine, and p-phenylenediamine; N-oxyls, such as a 4-hydroxy-TEMPO free radical and a 2,2,6,6-TEMPO free radical; and nitroso compounds such as N-nitrosodiphenylamine.

After the raw material for surface treatment has been prepared, in the surface treatment step, the raw material for surface treatment is heated to 110° C. or more by a dry process, to thereby prepare a surface-treated raw material containing the inorganic powder surface-treated with the silane coupling agent. Surface treatment methods are broadly classified into: a dry process involving spraying or dropping a silane coupling agent not mixed with a solvent onto a dried inorganic powder, to thereby directly mix the inorganic powder and the silane coupling agent; and a wet process involving adding a silane coupling agent to a solution having an inorganic powder dispersed in a dispersion medium. However, the wet process is liable to cause the occurrence of aggregates at the time of the removal of the solvent and involves a complicated operation, and hence, in the method of producing the surface-treated inorganic powder according to this embodiment, the surface treatment step is performed by the dry process. In the surface treatment by the dry process, its ambient gas is not limited, but in consideration of the suppression of a side reaction and safety, an inert gas, such as a helium gas or a nitrogen gas, is preferably used as the ambient gas, and a nitrogen gas is particularly preferably used.

In consideration of reactivity between the surface of the inorganic powder and the silane coupling agent, a heating temperature at the time of the surface treatment is preferably as high as possible, and hence, in the surface treatment step, the raw material for surface treatment is heated to 110° C. or more by the dry process. The heating temperature is more preferably 125° C. or more, still more preferably 135° C. or more. However, when the heating temperature is more than 200° C., the silane coupling agent and the polymerization inhibitor are liable to decompose, and hence the heating temperature is preferably 190° C. or less. A surface treatment reaction of a powder is generally performed through mixing by stirring or the like.

In the preparation of the raw material for surface treatment, when the silane coupling agent is supplied to a heated inorganic powder, there is a risk in that the reaction between the surface of the inorganic powder and the silane coupling agent may progress rapidly. Accordingly, the surface treatment step is preferably performed by preparing the raw material for surface treatment at a stage where the temperature of the inorganic powder is 100° C. or less, and then increasing the temperature to an intended heating temperature, and the surface treatment step is more preferably performed by preparing the raw material for surface treatment at a stage where the temperature is 60° C. or less, and then increasing the temperature to the intended heating temperature. A temperature increase rate is not particularly limited, but when the temperature increase rate is large, there is a fear in that the reaction vessel may locally have high temperature to make the surface treatment reaction nonuniform, or to cause double bonds contained in the silane coupling agent to polymerize. Accordingly, the temperature increase rate is preferably as small as possible. However, when the temperature increase rate is small, treatment efficiency becomes poor. In consideration of the foregoing, in the case of a reaction vessel having a volume of from about 0.1 m³ to about 1 m³, the temperature increase rate is preferably set to from 10° C./hr to 150° C./hr.

A method of heating the reaction vessel is not particularly limited, and a known method, such as a method involving circulating a fluid for temperature control in a jacket, or a method involving heating the outside of the reaction vessel with an infrared ray or the like, may be used. In addition, during the temperature increase, it is preferred that the inorganic powder and the silane coupling agent be continuously or intermittently mixed using a stirring blade or the like so as to be uniformly mixed. At this time, it is also preferred that the mixing be performed while the entirety of the reaction vessel is rotated and/or oscillated.

In the method of producing the surface-treated inorganic powder according to this embodiment, the surface treatment step is performed at a high temperature (110° C. or more) exceeding the boiling point of water as with the surface treatment method by the related-art dry process exemplified in JP 2016-052953 A and the like. Accordingly, in the surface treatment step, there is a concern that the polymerization activity (i.e., double bond) of the (meth)acryloyl group contained in the silane coupling agent may decrease/disappear. However, in the method of producing the surface-treated inorganic powder according to this embodiment, the decrease/disappearance of the polymerization activity (i.e., double bond) of the (meth)acryloyl group in the surface treatment step is significantly suppressed for reasons described below.

First, a commercially available silane coupling agent having a (meth)acryloyl group generally has added thereto about 0.01 mass % of a polymerization inhibitor. However, when the commercially available silane coupling agent is used as it is, and the silane coupling agent is bonded to the surface of inorganic powder under high temperature, it is conceived that the amount of the polymerization inhibitor added in advance to the silane coupling agent is excessively small, and hence the polymerization of the (meth)acryloyl group progresses to cause the decrease/disappearance of the polymerization activity (double bond) of the (meth)acryloyl group. However, in the method of producing the surface-treated inorganic powder according to this embodiment, a large of the amount polymerization inhibitor is newly and supplementally added to the commercially available silane coupling agent in the raw-material-for-surface-treatment preparation step. Consequently, in the raw material for surface treatment, the concentration of the polymerization inhibitor to be blended with the silane coupling agent is set to an extremely high concentration as compared to the commercially available silane coupling agent. Accordingly, in the method of producing the surface-treated inorganic powder according to this embodiment, the decrease/disappearance of the polymerization activity (i.e., double bond) of the (meth)acryloyl group in the surface treatment step is significantly suppressed, despite the fact that the surface treatment is performed at high temperature.

Here, in order to significantly suppress the decrease/disappearance of the polymerization activity (i.e., double bond) of the (meth)acryloyl group in the surface treatment step, in the raw-material-for-surface-treatment preparation step, the blending amount of the polymerization inhibitor (including the minute amount of the polymerization inhibitor blended in advance with the silane coupling agent) with respect to 100 parts by mass of the silane coupling agent having a (meth)acryloyl group is 0.3 part by mass or more, preferably 0.4 part by mass or more, more preferably 0.5 part by mass or more. Meanwhile, when the blending amount of the polymerization inhibitor is large, there is: a risk in that, at the time of the curing of the resin composition obtained by mixing the surface-treated inorganic powder and the curable resin, the curing reaction may be inhibited; a risk in that the removal of an excess amount of the polymerization inhibitor in a subsequent step (washing step) may become insufficient; or a risk in that the burden of the subsequent step (washing step) may be increased. Accordingly, in the raw-material-for-surface-treatment preparation step, the upper limit value of the blending amount of the polymerization inhibitor with respect to 100 parts by mass of the silane coupling agent having a (meth)acryloyl group is 50 parts by mass or less, preferably 45 parts by mass or less, more preferably 40 parts by mass or less.

### (Washing Step)

In the washing step, the surface-treated raw material obtained in the surface treatment step is washed. The washing step is a step performed for the main purpose of removing an excess amount of the polymerization inhibitor and an excess amount of an unreacted silane coupling agent (silane coupling agent physically adsorbed onto the surface of the inorganic powder) that are contained in the surface-treated raw material.

Unlike the surface treatment method based on the related-art dry process of JP 2016-052953 A or the like, the method of producing the surface-treated inorganic powder according to this embodiment involves blending a large amount of the polymerization inhibitor with the silane coupling agent in the raw-material-for-surface-treatment preparation step. Accordingly, as compared to the surface treatment method by the related-art dry process, in the method of producing the surface-treated inorganic powder according to this embodiment, an extremely large amount of the polymerization inhibitor remains in the surface-treated inorganic powder immediately after the surface treatment step has been performed. Then, when a large amount of the polymerization inhibitor remains in the surface-treated inorganic powder, at the time of the curing of the resin composition having blended thereinto the surface-treated inorganic powder, the reaction between the surface-treated inorganic powder and the curable resin is liable to be inhibited. In addition, when a large amount of the unreacted silane coupling agent (and a product of bonding between molecules of such silane coupling agent) remains in the surface-treated inorganic powder, there are risks in that: (1) at the time of the mixing of the surface-treated inorganic powder and the curable resin to prepare the resin composition, aggregates may be formed; and (2) at the time of the curing of the resin composition, its curing reaction may be inhibited, leading to the occurrence of a reduction or variation in mechanical strength of the cured body. However, the occurrence of those problems can be suppressed by performing the washing step.

The polymerization inhibitor and the unreacted silane coupling agent in an intermediate product obtained at least through the washing step or the surface-treated inorganic powder according to this embodiment serving as a final target product (both are hereinafter referred to as “object to be inspected”) may be recognized by a method described below.

First, when the object to be inspected contains a solvent component, the solvent component is removed to solidify the object to be inspected. Here, the polymerization inhibitor may be recognized by subjecting a methanol solution, which is obtained by bringing the object to be inspected into contact with methanol, to centrifugation treatment, and subjecting the resultant supernatant liquid to measurement using a gas chromatography-mass spectrometry (GC-MS) apparatus. In this case, the residual amount of the polymerization inhibitor in the object to be inspected, which is grasped by the measurement with the GC-MS apparatus, is preferably less than 50 ppm, more preferably less than 10 ppm. When the residual amount of the polymerization inhibitor is less than 50 ppm, at the time of the curing of the resin composition having blended thereinto the obtained final target product (surface-treated inorganic powder), the curing can be more reliably suppressed from becoming insufficient.

In addition, for the unreacted silane coupling agent, first, the object to be inspected that has been sufficiently subjected to drying treatment is subjected again to washing, solid-liquid separation, and drying. Then, a carbon amount X of the object to be inspected before this operation is performed, and a carbon amount Y of the object to be inspected after the operation has been performed are measured. Herein, the carbon amounts X and Y are measured by the same measurement method as the carbon amounts C1 and C2. In addition, a smaller difference (X−Y) between the carbon amount X and the carbon amount Y means that the residual amount of the unreacted silane coupling agent remaining in the object to be inspected before the above-mentioned operation is performed is also smaller. Accordingly, the difference (X−Y) between the carbon amounts is preferably less than 200 ppm, more preferably less than 100 ppm. When the difference (X−Y) between the carbon amounts is less than 200 ppm, at the time of the curing of the resin composition having blended thereinto the obtained final target product (surface-treated inorganic powder), the curing can be more reliably suppressed from becoming insufficient.

When the residual amount of the polymerization inhibitor is 50 ppm or more, and/or the difference (X−Y) between the carbon amounts is 200 ppm or more, in order to more reliably reduce the residual amounts of the polymerization inhibitor and the unreacted silane coupling agent to be contained in the final target product (surface-treated inorganic powder), it is preferred that (1) the washing step be repeatedly performed, (2) the washing conditions of the washing step be changed to conditions with higher washing properties, or (3) the above-mentioned (1) and (2) be performed in combination.

In the washing step, the surface-treated raw material is washed using a solvent to provide a washed raw material. As the solvent to be used in the washing step, there may be used without any limitation any solvent that is capable of uniformly dispersing the powder contained in the surface-treated raw material, dissolves the unreacted silane coupling agent and the polymerization inhibitor, and does not react with the silane coupling agent used for the surface treatment of the inorganic powder. Preferred examples of the solvent include: chain or cyclic saturated hydrocarbons, such as hexane, heptane, octane, cyclohexane, and cycloheptane; alcohols, such as methanol, ethanol, and isopropanol; and ketones, such as dimethyl ketone, methyl ethyl ketone, and diethyl ketone. Of those, alcohols and ketones are preferred from the viewpoints of, for example, safety, and ease with which a uniform slurry is obtained at the time of slurry preparation to be described later.

The washing step is not particularly limited as long as washing treatment involving bringing the surface-treated raw material into contact with a solvent is at least performed, but for example, it is preferred to perform treatment involving preparing a slurry having the surface-treated raw material dispersed in a solvent, and then subjecting the slurry to solid-liquid separation treatment.

In this case, equipment to be used for the preparation of the slurry is not limited, and a known apparatus, such as an ultrasonic dispersion apparatus or a stirring apparatus, may be used. A temperature at the time of the dispersion of the surface-treated raw material in a solvent (dispersion treatment temperature) is preferably set to be equal to or lower than the boiling point of the solvent to be used, and be 100° C. or less. A case in which the dispersion treatment temperature is 100° C. or more is not preferred because there is a fear in that polymerization or decomposition of the (meth)acryloyl group may occur.

In addition, as a method for the solid-liquid separation treatment, there may be used without any particular limitation any method capable of separating the solid matter and the solvent in the slurry, and performing the solid-liquid separation at a temperature of 100° C. or less. An apparatus to be used for the solid-liquid separation treatment is suitably an apparatus, such as a centrifuge, a centrifugal filter, or a filter press.

### (Foreign Matter Removal Step)

When the solid-liquid separation treatment is performed after the preparation of the slurry in the washing step, a foreign matter removal step may be performed as required after the preparation of the slurry and before the solid-liquid separation treatment. In the surface treatment step, there is also a considerable risk in that there may be formed coarse particles each resulting from a bonded body obtained through bonding between the silane coupling agents having (meth)acryloyl groups, or a polymerization product obtained through polymerization between the bonded body and an inorganic particle having the silane coupling agent having a (meth)acryloyl group bonded to the surface thereof. In addition, when the inorganic powder used in the surface treatment step contains the coarse particles, the coarse particles themselves tend to become coarse particles of the surface-treated inorganic powder. In such case, however, when the foreign matter removal step is performed, various kinds of foreign matter including the coarse particles can be removed from the obtained surface-treated inorganic powder according to this embodiment. Accordingly, the surface-treated inorganic powder according to this embodiment can be suitably utilized even in an application in which the presence of the coarse particles is not preferred.

In the foreign matter removal step, the slurry is subjected to wet filtration using a filter or the like to provide a filtered slurry from which the coarse particles and foreign matter other than the coarse particles (e.g., foreign matter mixed in from an environment in which the production is performed) have been removed. That is, the slurry is subjected to wet filtration to separate various kinds of foreign matter including the coarse particles on a filter medium. As the filter medium to be used for the filtration, there may be used without any particular limitation a filter medium having a filtration pore diameter in accordance with coarse particles and foreign matter other than coarse particles each having a large particle diameter unpreferred to be mixed into the surface-treated inorganic powder to be obtained. When the surface-treated inorganic powder to be obtained is used in an electronic material application, a filter medium having a filtration pore diameter of 50 μm or less is preferably used, and a filter medium having a filtration pore diameter of 30 μm or less is more preferably used. In a case in which the average particle diameter of the surface-treated inorganic powder to be obtained is 2 μm or less, when contamination with the coarse particles is to be prevented, it is preferred to use a filter medium having a filtration pore diameter of 3 μm or less. Meanwhile, when the filtration pore diameter of the filter medium to be used is excessively small, its filtration property is significantly reduced in some cases. Accordingly, the lower limit of the filtration pore diameter of the filter medium is generally 1 μm, though depending also on the average particle diameter of the surface-treated inorganic powder to be obtained.

A material for the filter medium is not particularly limited, but the filter medium is generally made of a resin (e.g., polypropylene or PTFE) or made of a metal. Of those, a filter medium made of a resin is preferably used from the viewpoint of preventing contamination with metal impurities. As a method of removing the coarse particles, there is also given a method involving dry-sieving the obtained surface-treated inorganic powder as a final step. However, when this method is utilized in an attempt to remove coarse particles having sizes of several micrometers by dry sieving, treatment efficiency is poor owing to the occurrence of clogging. Accordingly, the foreign matter removal step is suitably performed by a wet process using a filter medium, rather than by a dry process using a sieve.

### (Drying Step)

The washed raw material that has been obtained through the washing step may be naturally dried to provide the surface-treated inorganic powder serving as the final target product, but it is generally preferred that the washed raw material be subjected to drying treatment to provide the surface-treated inorganic powder serving as the final target product. A known dryer may be used for the drying treatment, and for example, a vacuum dryer or an air-blow dryer may be suitably used. In the case of performing drying under reduced pressure, the pressure only needs to be appropriately controlled, but it is important to select a drying temperature at which the polymerization of the (meth)acryloyl group contained in the silane coupling agent by heat can be suppressed. When the drying is performed at high temperature, the polymerization can be suppressed if a drying time is short. However, when, for example, the drying conditions of 100° C. and 24 hours are adopted, the polymerization of the (meth)acryloyl group occurs in some cases. Accordingly, when 24 hours or more of drying treatment is performed, the drying temperature is preferably 100° C. or less, more preferably 90° C. or less, still more preferably 80° C. or less.

### EXAMPLES

The present invention is more specifically described below by way of Examples together with Comparative Examples, but the present invention is not limited to these Examples. Measurement methods for various physical property values and characteristic values used for the evaluations of the following Examples and Comparative Examples are as described below.

### 1 Presence Amounts of Double Bonds (D1 and D2)

A presence amount D1 of double bonds per unit surface area of a surface-treated inorganic powder, and a presence amount D2 of double bonds per unit surface area of a washed powder were determined on the basis of the following equations.

Presence amount D1 of double bonds (μmol/m²)=amount of double bonds per unit mass of surface-treated inorganic powder (μmol/g)/specific surface area of inorganic powder (m²/g)

Presence amount D2 of double bonds (μmol/m²)=amount of double bonds per unit mass of washed powder (μmol/g)/specific surface area of inorganic powder (m²/g)

A method of measuring the amount of double bonds per unit mass of each of the surface-treated inorganic powder and the washed powder and the specific surface area of the inorganic powder, and a method of preparing the washed powder are described in Sections 1.1 to 1.3 below.

### 1.1 Measurement of Amount of Double Bonds Per Unit Mass

The amount of double bonds per unit mass of each of the surface-treated inorganic powder and the washed powder (hereinafter in the description of this section, both are referred to as “powder to be measured”) was determined by being quantified in conformity with Wijs' method (“JIS K 0070-1992 Test methods for acid value, saponification value, ester value, iodine value, hydroxyl value and unsaponifiable matter of chemical products”). Specifically, a solution prepared by dispersing about 1.0 g of the powder to be measured in 3 mL of cyclohexane, and then adding 0.7 mL of a commercially available Wijs solution (FUJIFILM Wako Pure Chemical Corporation, for iodine value titration, 0.1 mol/l iodine monochloride-acetic acid solution, factor: 0.9 to 1.0) is hermetically sealed and then stirred at normal temperature in a dark place for 1 hour. A sample liquid prepared by adding, to the solution, 1 mL of a 10% potassium iodide solution and 4 mL of pure water is titrated with 0.01 mol/L sodium thiosulfate (FUJIFILM Wako Pure Chemical Corporation, for volumetric analysis). At the time point when the sample liquid is titrated until its color becomes pale yellow, two or three drops of a 1% aqueous starch solution are added as an indicator to continue titration, and a value at which the color of the sample liquid has become transparent is defined as an endpoint. In addition, as a blank test, a sample liquid (reference liquid) prepared by the same procedure without using the powder to be measured was also titrated. Then, the amount of double bonds per g of the powder to be measured was calculated on the basis of the following equation.

Amount of double bonds per g of powder to be measured (μmol/g)=[0.01×F×(B−D)×10⁻³/(2×m)]×10⁶
B: the amount (mL) of the 0.01 mol/L sodium thiosulfate solution used for the titration of the reference liquid used for the blank test
D: the amount (mL) of the 0.01 mol/L sodium thiosulfate solution used for the titration of the sample liquid
F: the factor of the 0.01 mol/L sodium thiosulfate solution (For the calculation of the amount of double bonds based on the above-mentioned equation, the calculation was performed assuming F=1.0.)
m: the collected amount (g) of the powder to be measured

### 1.2 Measurement of Specific Surface Area of Inorganic Powder

The specific surface area (m²/g) of the inorganic powder used for the production of the surface-treated inorganic powder was measured using a specific surface area-measuring apparatus SA-1000 (manufactured by Sibata Scientific Technology Ltd.) by a BET one-point method based on a nitrogen adsorption amount. The specific surface area of the surface-treated inorganic powder shown in a table to be described later was also similarly measured.

### 1.3 Preparation Procedure for Washed Powder

The washed powder was prepared by sequentially subjecting the surface-treated inorganic powder to treatments shown in the following (1) to (3):
(1) 50 mL of methanol and 10 g of the surface-treated inorganic powder are mixed to provide a dispersion liquid;
(2) the dispersion liquid is treated with an ultrasonic disperser at an output of 40 W for 20 minutes to provide a slurry; and
(3) solid matter obtained by centrifuging the slurry and removing a supernatant is dried under reduced pressure at a pressure of 0.1 MPa and a temperature of 50° C. for a treatment time of 12 hours to provide the washed powder.
   2 Ratio (D1/D2) between Presence Amounts of Double Bonds

A ratio (D1/D2) between presence amounts of double bonds was determined on the basis of the presence amount (D1) of double bonds of the surface-treated inorganic powder and the presence amount (D2) of double bonds of the washed powder determined by the procedure described in Section 1 above.

### 3 Carbon Content Per Unit Surface Area, and Difference (C1-C2) Between Carbon Amounts

### 3.1 Carbon Content per Unit Surface Area

The carbon content per unit surface area of the surface-treated inorganic powder was calculated on the basis of the following equation through use of the values of: a carbon amount (C1) per unit mass of the surface-treated inorganic powder described in Section 3.3; and the specific surface area of the inorganic powder measured by the procedure described in Section 1.2. In the following equation, “carbon amount (C1) (μg/g)/12.01” means a carbon content per unit mass (μmol/g). In addition, for reference, 1 μg/g=1 ppm.

Carbon content (μmol/m²)=(carbon amount (C1) (μg/g)/12.01)/specific surface area (m²/g)

### 3.2 Difference (C1-C2) Between Carbon Amounts

A difference (C1-C2) (ppm) between carbon amounts was determined on the basis of the carbon amount (C1) of the surface-treated inorganic powder and the carbon amount (C2) of the washed powder.

### 3.3 Measurement of Carbon Amounts C1 and C2

For the carbon amounts C1 and C2 (ppm) mentioned in Section 3.1 and Section 3.2 above, the powder to be measured (surface-treated inorganic powder or washed powder) was subjected to measurement by a combustion oxidation method. EMIA-511 manufactured by Horiba, Ltd. was used for the measurement. Specifically, the carbon amount (ppm) contained in the powder to be measured was determined from the amount of carbon dioxide produced by heating the powder to be measured in an oxygen atmosphere to 1, 350° C. The powder to be measured that was to be subjected to the measurement was subjected to pretreatment involving heating at 80° C. and pressure reduction in the system to remove moisture adsorbed in the air and the like, and was then used for the measurement of the carbon amount.

### 4 Measurement of Residual Amount of Polymerization Inhibitor in Surface-treated Inorganic Powder

The residual amount of a polymerization inhibitor in the surface-treated inorganic powder was measured by the following procedure. First, 3 g of the surface-treated inorganic powder was placed in a centrifuge tube, 30 mL of methanol was added, and the mixture was stirred. After that, the solution in the centrifuge tube was centrifuged, and the resultant supernatant liquid was placed in a recovery flask and concentrated under reduced pressure using an evaporator until the volume of the supernatant liquid became 1 mL or less. The concentrated supernatant liquid was accurately diluted to 5 mL with methanol, and centrifuged and diluted again if required, and the thus obtained diluted liquid was used as a measurement sample. In addition, there were prepared a plurality of kinds of standard samples different in concentration, which were prepared so as to contain 1 ppm to 100 ppm of a polymerization inhibitor used in the surface treatment of the inorganic powder. About 1 mg of the measurement sample was wrapped in Pyrofoil and pyrolyzed at 590° C. for 5 seconds, and the thus generated gas was analyzed by GC-MS (HP 6890 (GC) and HP 5973 (MS) manufactured by Agilent). In addition, the standard samples were also similarly subjected to measurement. Through the GC-MS analysis and through use of a calibration curve obtained from standard samples, measurement of the measurement sample was performed, and the residual amount of the polymerization inhibitor in the surface-treated inorganic powder was determined.

### 5 Intensity Ratio (M/N) in ¹³C CP MAS NMR

An NMR spectrum of the surface-treated inorganic powder was measured using AVANCE II 500 manufactured by Bruker Biospin and using a 4 mm MAS probe at a rotation frequency of 7 kHz, a contact time of 1.5 milliseconds, and a number of scans of 20,000. A peak height (M) within the range of from 120 ppm to 150 ppm and a peak height (N) within the range of from 0 ppm to +10 ppm were read from the resultant NMR spectrum, and an intensity ratio (M/N) was determined on the basis of those peak heights.

### 6 Sphericity

The shape of each of the inorganic powder and the surface-treated inorganic powder was observed with an SEM (manufactured by JEOL Datum Ltd., JSM-6060) to determine a sphericity. Specifically, 1,000 or more particles were observed, and the sphericity of each of the particles was measured using an image processing program (manufactured by Soft Imaging System GmbH, AnalySIS), followed by the determination of the average value thereof. The sphericity was calculated by the following equation.

Sphericity=4π×(area)/(perimeter)²

### 7 Number Analysis of Coarse Particles

Measurement of coarse particles contained in each of the surface-treated inorganic powder and the inorganic powder (hereinafter in the description of this section, both are referred to as “powder to be measured”) was performed with a Coulter counter (manufactured by Beckman Coulter, Inc., Multisizer 3). In this measurement, a range in which the number of particles can be measured differs depending on an aperture size to be used, and hence an aperture corresponding to coarse particles was selected after the average particle diameter of the powder to be measured had been measured in advance by a method described in Section 8 below. Specifically, individual particle diameters of the powder to be measured were measured by the following procedure using an aperture diameter of 30 μm in the measurement of coarse particles in which the particle diameter of each of the coarse particles was 5 μm or less (i.e., the average particle diameter was 1 μm or less), and an aperture diameter of 50 μm in the measurement of coarse particles in which the particle diameter of each of the coarse particles was 20 μm or less (i.e., the average particle diameter was 4 μm or less).

First, 1 g of the powder to be measured that had been weighed in an electronic balance, and 19 g of ethanol were added into a 50 mL glass bottle, and the thus prepared mixed liquid was subjected to dispersion treatment using an ultrasonic homogenizer (manufactured by Branson, Sonifier 250) under the conditions of 40 W and 10 minutes to provide a measurement sample. At this time, a total of five similar measurement samples were prepared. In this case, the number of measurement particles per sample was set to about 50,000, and measurement was performed for about 250,000 particles as a total for the five samples. Then, of the population (about 250,000 particles) corresponding to the total measurement number, the number of particles each having a particle diameter 5 or more times as large as the average particle diameter (number of coarse particles) was calculated, and the amount of the coarse particles (ppm) was determined on the basis of the total measurement number and the number of coarse particles.

### 8 Average Particle Diameter and Coefficient of Variation CV

The average particle diameter and coefficient of variation CV of each of the surface-treated inorganic powder and the inorganic powder (hereinafter in the description of this section, both are referred to as “powder to be measured”) were measured by the following procedure. First, about 0.1 g of the powder to be measured that had been weighed in an electronic balance, and about 40 mL of a solvent (distilled water or ethanol) were added into a 50 mL glass bottle, and the thus prepared mixed liquid was dispersed using an ultrasonic homogenizer (manufactured by Branson, Sonifier 250) under the conditions of 40 W and 10 minutes to prepare a measurement sample. Next, the measurement sample was used and measured for a volume-based average particle diameter (μm) and a coefficient of variation CV (%) with a laser diffraction/scattering particle size distribution analyzer (manufactured by Beckman Coulter, Inc., LS-13 320). Herein, the average particle diameter (μm) means a volume-based 50% cumulative diameter.

### 9 Bending Failure Stress Measurement

For a cured body, the bending failure stress of the cured body was measured using a tensile testing machine (manufactured by Toyo Seiki Seisaku-sho, Ltd., Strograph M-2) in conformity with JIS K 7171:2016.

### <Inorganic Powders A to I>

Inorganic powders A to I shown in Table 1 were used as inorganic powders used for the production of surface-treated inorganic powders of Examples and Comparative Examples to be described later. Table 1 shows the substance name of each inorganic powder, a production process for the inorganic powder, and its average particle diameter, CV, sphericity, content of coarse particles, and specific surface area.

TABLE 1

| | | Production | Average | | | Coarse | Specific |
|---|---|---|---|---|---|---|---|
| Inorganic | | process for | particle | | | particles | surface |
| powder | Substance | inorganic | diameter | CV | | (*3) | area |
| No. | name | powder | (μm) | (%) | Sphericity | (ppm) | (m²/g) |
| A | Silica | Sol-gel | 0.74 | 22 | 0.96 | 0 | 3.9 |
| | | process | | | | | |
| B | Silica | Sol-gel | 0.11 | 26 | 0.98 | 8 | 23.5 |
| | | process | | | | | |
| C | Silica | Sol-gel | 0.41 | 23 | 0.96 | 0 | 6.6 |
| | | process | | | | | |
| D | Silica | Sol-gel | 1.08 | 25 | 0.97 | 0 | 2.8 |
| | | process | | | | | |
| E | Silica | Sol-gel | 1.46 | 28 | 0.96 | 0 | 2.0 |
| | | process | | | | | |
| F | Silica | Dry | 0.36 | 52 | 0.94 | 0 | 7.3 |
| | | process | | | | | |
| G | Silica | Dry | 3.51 | 57 | 0.93 | 70 | 1.6 |
| | | process | | | | | |
| H | Composite | Sol-gel | 0.43 | 31 | 0.95 | 3 | 6.2 |
| | ST (*1) | process | | | | | |
| I | Composite | Sol-gel | 0.39 | 35 | 0.89 | 5 | 6.3 |
| | SZ (*2) | process | | | | | |

*1 Silica-titania composite oxide (silica: 95 mol %)
*2 Silica-zirconia composite oxide (silica: 92 mol %)
*3 Particles more than 5 times as large as average particle diameter of inorganic powder

### Example 1

### (Raw-Material-for-Surface-Treatment Preparation Step)

To 971 g of methacryloxypropyltrimethoxysilane (MPTS, containing BHT at a concentration of 0.02 mass %), 108 g of dibutylhydroxytoluene (BHT) was added to provide a surface treatment agent mixture. In this case, the blending amount of the polymerization inhibitor (BHT) with respect to 100 parts by mass of the silane coupling agent having a (meth)acryloyl group (MPTS) is 11.1 parts by mass (i.e., concentration of the polymerization inhibitor: 10 mass %). Subsequently, 50 kg of the inorganic powder A was placed in an oscillation-rotation-type reaction apparatus (inner diameter: 500 mm) including a reaction vessel having a volume of 150 L having arranged thereinside a blade for disintegration (diameter: 20 cm, width: 5 cm), and a N₂ gas was supplied into the reaction vessel at a flow rate of 60 L/min for 10 minutes under a state in which the number of rotations and number of oscillations of the reaction vessel were set to 10 rotations/min and 5 oscillations/min, respectively, and the number of rotations of the blade for disintegration was set to 800 rotations/min. Then, under a state in which the rotation/oscillation of the above-mentioned reaction vessel, and the rotation of the blade for disintegration were continued, the surface treatment agent mixture was supplied into the reaction vessel under room temperature over 60 minutes. After the completion of the supply of the surface treatment agent mixture, the mixture of the inorganic powder A and the surface treatment agent mixture (raw material for surface treatment) in the reaction vessel was continuously mixed for 60 minutes.

### (Surface Treatment Step)

After that, while the mixing of the raw material for surface treatment was continued, the reaction vessel was heated to increase the temperature of the raw material for surface treatment at a rate of 2° C./min. The temperature of the raw material for surface treatment in the reaction vessel was monitored with a thermocouple mounted in the reaction vessel. In addition, the temperature of the raw material for surface treatment was increased to 150° C., and the mixing of the raw material for surface treatment was continued for 3 hours under a state in which the temperature of the raw material for surface treatment was maintained at 150° C. Thus, a surface-treated raw material was obtained.

### (Washing Step and Foreign Matter Removal Step)

After the completion of the surface treatment step, 15 kg of methanol was placed in a container made of SUS having an internal volume of 40 liters, and while the methanol was stirred with a propeller-type stirrer at a stirring speed of 100 rpm, 5 kg of the surface-treated raw material was further added, and the stirring was continued for 60 minutes, to thereby prepare a dispersion liquid having a slurry concentration of 25 mass %. Then, the dispersion liquid was fed with a diaphragm pump at a rate of 1 L/min and passed through a filtration filter made of polypropylene having a filtration pore diameter of 3 μm, to thereby remove foreign matter. The dispersion liquid after the filtration was subjected to pressure filtration through a filter cloth having an air permeability of 0.6 cm³/(cm²·s) to recover 6 kg of an undried surface-treated raw material as a cake.

### (Drying Step)

Then, the cake formed of the undried surface-treated raw material was dried under reduced pressure at a pressure of 0.1 Pa and a temperature of 60° C. for 24 hours to provide 4.6 kg of a surface-treated inorganic powder. In the ¹³C CP MAS NMR spectrum of the resultant surface-treated inorganic powder, the intensity ratio (M/N) between the peak height (M) within the range of from 120 ppm to 150 ppm and the peak height (N) within the range of from 0 ppm to +10 ppm was 2.12. The surface-treated inorganic powder had a specific surface area of 3.9 m²/g, a carbon content per unit surface area of 69.0 μmol/m², a presence amount D1 of double bonds of 6.8 μmol/m², a sphericity of 0.96, a content of coarse particles of 0 ppm, and a content of the polymerization inhibitor of less than 10 ppm. The production conditions of the surface-treated inorganic powder of Example 1 are shown in Tables 2 and 3, and various characteristics of the surface-treated inorganic powder of Example 1 are shown in Tables 4 and 5 (The same applies to other Examples and Comparative Examples to be described later).

TABLE 2

| | | | Silane coupling agent | | | | | |
|---|---|---|---|---|---|---|---|---|
| | | | | | | Theo- | | Usage |
| | Inorganic powder | | | Usage | Minimum | retical | | amount |
| | Inorganic | Usage | | amount | coverage | bonded | Usage | (parts |
| | powder | amount | | (μmol/ | area | amount | amount | by |
| | No. | (kg) | Kind | m²) | (m²/g) | (g) | (g) | weight) |
| Example 1 | A | 50 | MPTS | 20 | 314 | 623 | 971 | 100 |
| Example 2 | B | 50 | MPTS | 20 | 314 | 3,744 | 5,840 | 100 |
| Example 3 | C | 50 | APTS | 20 | 333 | 983 | 1,627 | 100 |
| Example 4 | D | 50 | MPTS | 20 | 314 | 447 | 698 | 100 |
| Example 5 | E | 50 | MPTS | 40 | 314 | 322 | 1,004 | 100 |
| Example 6 | F | 50 | MPTS | 20 | 314 | 1,154 | 1,801 | 100 |
| Example 7 | G | 50 | MPTS | 20 | 314 | 258 | 402 | 100 |
| Example 8 | A | 50 | MPTS | 20 | 314 | 623 | 971 | 100 |
| Example 9 | A | 50 | MPTS | 40 | 314 | 623 | 1,942 | 100 |
| Example 10 | A | 50 | MPTS | 20 | 314 | 623 | 971 | 100 |
| Example 11 | H | 50 | MPTS | 20 | 314 | 981 | 1,530 | 100 |
| Example 12 | I | 50 | MPTS | 20 | 314 | 1,006 | 1,570 | 100 |
| Comparative | A | 50 | MPTS | 20 | 314 | 623 | 971 | 100 |
| Example 1 | | | | | | | | |
| Comparative | C | 50 | MPTS | 20 | 314 | 1,043 | 1,627 | 100 |
| Example 2 | | | | | | | | |
| Comparative | A | 50 | MPTS | 20 | 314 | 623 | 971 | 100 |
| Example 3 | | | | | | | | |
| Comparative | A | 50 | MPTS | 80 | 314 | 623 | 3,885 | 100 |
| Example 4 | | | | | | | | |

TABLE 3

| | Polymerization inhibitor (*) | | | | | | | |
|---|---|---|---|---|---|---|---|---|
| | | Usage | | Usage | Reaction | Steps | | |
| | | amount | Usage | amount | temper- | | | Foreign |
| | | (μmol/ | amount | (parts by | ature | Surface | | matter |
| | Kind | m²) | (g) | weight) | (° C.) | treatment | Washing | removal |
| Example 1 | BHT | 2.5 | 108 | 11.1 | 150 | Dry process | Present | Present |
| Example 2 | BHT | 2.5 | 648 | 11.1 | 150 | Dry process | Present | Present |
| Example 3 | TBHQ | 3.3 | 181 | 11.1 | 150 | Dry process | Present | Present |
| Example 4 | BHT | 2.5 | 77 | 11.1 | 130 | Dry process | Present | Present |
| Example 5 | BHT | 5.0 | 111 | 11.1 | 150 | Dry process | Present | Present |
| Example 6 | BHT | 2.5 | 200 | 11.1 | 150 | Dry process | Present | Absent |
| Example 7 | BHT | 2.5 | 45 | 11.1 | 150 | Dry process | Present | Absent |
| Example 8 | BHT | 2.5 | 108 | 11.1 | 150 | Dry process | Present | Absent |
| Example 9 | BHT | 5.0 | 216 | 11.1 | 150 | Dry process | Present | Present |
| Example 10 | BHT | 9.7 | 417 | 42.9 | 150 | Dry process | Present | Present |
| Example 11 | BHT | 2.5 | 170 | 11.1 | 150 | Dry process | Present | Present |
| Example 12 | BHT | 2.5 | 174 | 11.1 | 150 | Dry process | Present | Present |
| Comparative | BHT | 0.005 | 0.19 | 0.0002 | 150 | Dry process | Present | Absent |
| Example 1 | | | | | | | | |
| Comparative | TBHQ | 0.006 | 0.33 | 0.0002 | 80 | Dry process | Present | Present |
| Example 2 | | | | | | | | |
| Comparative | BHT | 2.5 | 108 | 11.1 | 150 | Dry process | Absent | Absent |
| Example 3 | | | | | | | | |
| Comparative | BHT | 10 | 432 | 11.1 | 150 | Dry process | Present | Absent |
| Example 4 | | | | | | | | |

*The kind and usage amount of the polymerization inhibitor used in each of Comparative Examples 1 and 2 derived only from the polymerization inhibitor blended in advance with the silane coupling agent.

TABLE 4

| | | Surface-treated inorganic powder (D2 and C2 mean values of washed powder) | | | | | | | |
|---|---|---|---|---|---|---|---|---|---|
| | | | | | | | | Difference | |
| | Inorganic | Presence amount of | | | | | | C1 − C2 | |
| | powder | double bonds | | | Carbon | | | (ppm) | Intensity |
| | Inorganic | D1 | D2 | | content | Carbon amount | | between | ratio |
| | powder | (μmol/ | (μmol/ | | (μmol/ | C1 | C2 | carbon | (M/N) |
| | No. | m²) | m²) | D1/D2 | m²) | (ppm) | (ppm) | amounts | (*) |
| Example 1 | A | 6.8 | 6.7 | 1.01 | 69.0 | 3,256 | 3,214 | 42 | 2.12 |
| Example 2 | B | 5.9 | 5.9 | 1.00 | 61.4 | 17,385 | 17,292 | 93 | 1.78 |
| Example 3 | C | 6.2 | 6.1 | 1.02 | 58.7 | 4,652 | 4,632 | 20 | 1.62 |
| Example 4 | D | 5.3 | 5.3 | 1.00 | 54.1 | 1,826 | 1,811 | 15 | 2.46 |
| Example 5 | E | 7.1 | 6.8 | 1.04 | 129.1 | 3,155 | 3,101 | 54 | 0.90 |
| Example 6 | F | 4.8 | 4.8 | 1.00 | 52.8 | 4,600 | 4,532 | 68 | 2.13 |
| Example 7 | G | 12.3 | 12.0 | 1.03 | 107.8 | 2,113 | 2,088 | 25 | 2.50 |
| Example 8 | A | 6.1 | 5.8 | 1.05 | 75.8 | 3,568 | 3,492 | 76 | 2.32 |
| Example 9 | A | 23.1 | 21.7 | 1.06 | 177.3 | 8,320 | 8,231 | 89 | 3.70 |
| Example 10 | A | 10.6 | 10.4 | 1.02 | 88.7 | 4,162 | 4,074 | 88 | 4.20 |
| Example 11 | H | 4.6 | 4.5 | 1.02 | 69.3 | 5,115 | 5,063 | 52 | 1.60 |
| Example 12 | I | 4.0 | 4.0 | 1.00 | 48.8 | 3,667 | 3,613 | 54 | 1.80 |
| Comparative | A | 0.2 | 0.2 | 1.00 | 128.3 | 5,635 | 5,578 | 57 | 0.20 |
| Example 1 | | | | | | | | | |
| Comparative | C | 0.4 | 0.4 | 1.00 | 6.4 | 507 | 497 | 10 | 0.24 |
| Example 2 | | | | | | | | | |
| Comparative | A | 16.3 | 14.2 | 1.15 | 135.0 | 6,371 | 5,534 | 837 | 2.10 |
| Example 3 | | | | | | | | | |
| Comparative | A | 54.2 | 51.3 | 1.06 | 344.8 | 16,177 | 15,979 | 198 | 3.65 |
| Example 4 | | | | | | | | | |

*Intensity ratio in NMR spectrum

TABLE 5

| | | Surface-treated inorganic powder | | | | | |
|---|---|---|---|---|---|---|---|
| | Inorganic | Other characteristic values | | | | | |
| | powder | Average | | | Coarse | Specific | Poly- |
| | Inorganic | particle | | | particles | surface | merization |
| | powder | diameter | CV | | (*) | area | inhibitor |
| | No. | (μm) | (%) | Sphericity | (ppm) | (m²/g) | (ppm) |
| Example 1 | A | 0.74 | 23 | 0.96 | 0 | 3.9 | <10 |
| Example 2 | B | 0.13 | 27 | 0.97 | 10 | 23.4 | <10 |
| Example 3 | C | 0.42 | 23 | 0.96 | 0 | 6.6 | <10 |
| Example 4 | D | 1.08 | 28 | 0.96 | 0 | 2.8 | <10 |
| Example 5 | E | 1.47 | 29 | 0.96 | 0 | 2.0 | <10 |
| Example 6 | F | 0.38 | 52 | 0.92 | 10 | 7.2 | <10 |
| Example 7 | G | 3.65 | 73 | 0.93 | >100 | 1.6 | <10 |
| Example 8 | A | 0.75 | 24 | 0.95 | 5 | 3.9 | <10 |
| Example 9 | A | 0.74 | 27 | 0.96 | 0 | 3.9 | <10 |
| Example 10 | A | 0.74 | 24 | 0.96 | 0 | 3.9 | <10 |
| Example 11 | H | 0.46 | 33 | 0.95 | 0 | 6.1 | <10 |
| Example 12 | I | 0.43 | 39 | 0.84 | 0 | 6.2 | <10 |
| Comparative | A | 1.08 | 43 | 0.94 | >100 | 3.6 | <10 |
| Example 1 | | | | | | | |
| Comparative | C | 0.44 | 25 | 0.95 | 5 | 6.6 | <10 |
| Example 2 | | | | | | | |
| Comparative | A | 0.77 | 25 | 0.96 | 30 | 3.9 | 530 |
| Example 3 | | | | | | | |
| Comparative | A | 1.10 | 95 | 0.95 | — | 3.8 | <10 |
| Example 4 | | | | | | | |

*Particles more than 5 times as large as average particle diameter of surface-treated inorganic powder

### (Production of Resin Composition and Cured Body)

15 g of pentaerythritol tetraacrylate, 0.15 g of 1-hydroxycyclohexyl phenyl ketone (Irgacure 184), and 15 g of the surface-treated inorganic powder were mixed, and then preliminarily kneaded with a rotation-revolution mixer (Awatori Rentaro AR-500 manufactured by Thinky Corporation) (kneading: at 1,000 rpm for 8 min, defoaming: at 2,000 rpm for 2 min) to produce a kneaded product. Further, the kneaded product was sufficiently subjected to dispersion treatment by being passed through a triple roll mill set to a gap of 20 μm 8 times. Thus, a paste-like resin composition was obtained. Subsequently, the resultant resin composition was placed in a mold made of silicon, and was then irradiated with UV light at 9 W to provide a cured body (size: 2×2×25 mm).

### Example 2

A surface-treated inorganic powder, a resin composition, and a cured body were obtained by performing each step under the same conditions as in Example 1 except that the inorganic powder B was used.

### Example 3

A surface-treated inorganic powder, a resin composition, and a cured body were obtained by performing each step under the same conditions as in Example 1 except that: the inorganic powder C was used; acryloxypropyltrimethoxysilane (APTS) was used as the surface treatment agent; and tert-butylhydroquinone (TBHQ) was used as the polymerization inhibitor.

### Example 4

A surface-treated inorganic powder, a resin composition, and a cured body were obtained by performing each step under the same conditions as in Example 1 except that the inorganic powder D was used.

### Example 5

A surface-treated inorganic powder, a resin composition, and a cured body were obtained by performing each step under the same conditions as in Example 1 except that: the inorganic powder E was used; and the amount of the treatment agent to be added was changed to 40 μmol/m².

### Example 6

A surface-treated inorganic powder, a resin composition, and a cured body were obtained by performing each step under the same conditions as in Example 1 except that: the inorganic powder F was used; and in the washing and foreign matter removal steps, the removal of foreign matter using the filtration filter made of polypropylene having a filtration pore diameter of 3 μm was not performed.

### Example 7

A surface-treated inorganic powder, a resin composition, and a cured body were obtained by performing each step under the same conditions as in Example 1 except that: the inorganic powder G was used; and in the washing and foreign matter removal steps, the removal of foreign matter using the filtration filter made of polypropylene having a filtration pore diameter of 3 μm was not performed.

### Example 8

A surface-treated inorganic powder, a resin composition, and a cured body were obtained by performing each step under the same conditions as in Example 1 except that, in the washing and foreign matter removal steps, the filtration filter made of polypropylene having a filtration pore diameter of 3 μm was not used.

### Example 9

In the surface treatment step of Example 1, after 50 kg of the inorganic powder A had been placed in the oscillation-rotation-type reaction apparatus having a volume of 150 L (inner diameter: 500 mm), air having a humidity of 20% was supplied into the reaction vessel at a flow rate of 60 L/min for 30 minutes under a state in which the number of rotations and number of oscillations of the reaction vessel were set to 10 rotations/min and 5 oscillations/min, respectively, and the number of rotations of the blade for disintegration was set to 800 rotations/min. Then, under a state in which rotation/oscillation of the above-mentioned reaction vessel, and the rotation of the blade for disintegration were continued, a surface treatment agent mixture (2,158 g of a mixture of 1,942 g of MPTS and 216 g of BHT) was supplied into the reaction vessel under room temperature over 60 minutes. A surface-treated inorganic powder, a resin composition, and a cured body were obtained by performing each step under the same conditions as in Example 1 except the above-mentioned points.

### Example 10

A surface-treated inorganic powder, a resin composition, and a cured body were obtained by performing each step under the same conditions as in Example 1 except that a surface treatment agent mixture obtained by adding BHT to methacryloxypropyltrimethoxysilane (BHT concentration: 0.02 mass %) so as to have a BHT concentration of 30 mass % was used.

### Example 11

A surface-treated inorganic powder, a resin composition, and a cured body were obtained by performing each step under the same conditions as in Example 1 except that the inorganic powder H of a silica-titania composite oxide (silica: 95 mol %) was used as the inorganic powder.

### Example 12

A surface-treated inorganic powder, a resin composition, and a cured body were obtained by performing each step under the same conditions as in Example 1 except that the inorganic powder I of a silica-zirconia composite oxide (silica: 92 mol %) was used as the inorganic powder.

### Comparative Example 1

A surface-treated inorganic powder, a resin composition, and a cured body were obtained by performing each step under the same conditions as in Example 1 except that: the polymerization inhibitor was not separately added to methacryloxypropyltrimethoxysilane; and the foreign matter removal step was not performed. The foreign matter removal step was not performed because, even when an attempt was made to filter the surface-treated raw material after the washing treatment through the filtration filter made of polypropylene, the filter was clogged.

### Comparative Example 2

A surface-treated inorganic powder, a resin composition, and a cured body were obtained by performing each step under the same conditions as in Example 3 except that: the polymerization inhibitor was not separately added to methacryloxypropyltrimethoxysilane; and the heating temperature in the surface treatment step was changed to 80° C.

### Comparative Example 3

A surface-treated inorganic powder, a resin composition, and a cured body were obtained by performing each step under the same conditions as in Example 1 except that the washing and foreign matter removal steps were not performed.

### Comparative Example 4

In the surface treatment step of Example 9, the air having a humidity of 20% to be supplied to the reaction vessel was supplied at a flow rate of 60 L/min for 60 minutes, and a mixture of 3,885 g of MPTS and 432 g of BHT was used as the surface treatment agent mixture added. In addition, in the washing step, the foreign matter removal operation was not performed. A surface-treated inorganic powder, a resin composition, and a cured body were obtained by performing each step under the same conditions as in Example 9 except the above-mentioned points.

### (Bending Failure Stress Measurement)

Bending failure stress measurement was performed for each of the cured bodies obtained by curing the resin compositions having blended thereinto the surface-treated inorganic powders obtained in Examples 1 to 12 and Comparative Examples 1 to 4. The results are shown in Table 6. It is found that the bending failure stress tends to be high when the presence amount D1 of double bonds of the surface-treated inorganic powder is from 3.0 (μmol/m²) to 50.0 (μmol/m²) and the ratio (D1/D2) between the presence amounts of double bonds is less than 1.10. The fracture surface of each of the cured bodies after the test was observed with a scanning electron microscope (SEM). As a result, the cured bodies obtained in Examples 1 to 12 were each found to have undergone cohesive failure involving a fracture of a resin portion, whereas the cured body of Comparative Example 1 was found to have undergone interfacial failure involving peeling at an interface between the surface-treated inorganic powder and the resin (none shown). It is conceived that, when the number of covalent bonds formed between the resin and the surface of the surface-treated inorganic powder at the time of curing is large, cohesive failure occurs, and hence the bending failure stress is high.

TABLE 6

| | Surface-treated inorganic powder | | Cured body |
|---|---|---|---|
| | Presence amount D1 | | Failure |
| | of double bonds | D1/D2 | stress |
| | (μmol/m²) | (*) | (MPa) |
| Example 1 | 6.8 | 1.01 | 130 |
| Example 2 | 5.9 | 1.00 | 127 |
| Example 3 | 6.2 | 1.02 | 125 |
| Example 4 | 5.3 | 1.00 | 118 |
| Example 5 | 7.1 | 1.04 | 139 |
| Example 6 | 4.8 | 1.00 | 121 |
| Example 7 | 12.3 | 1.03 | 152 |
| Example 8 | 6.1 | 1.05 | 116 |
| Example 9 | 23.1 | 1.06 | 186 |
| Example 10 | 10.6 | 1.02 | 99 |
| Example 11 | 4.6 | 1.02 | 132 |
| Example 12 | 4.0 | 1.00 | 114 |
| Comparative | 0.2 | 1.00 | 65 |
| Example 1 | | | |
| Comparative | 0.4 | 1.00 | 71 |
| Example 2 | | | |
| Comparative | 16.3 | 1.15 | 75 |
| Example 3 | | | |
| Comparative | 54.2 | 1.06 | 58 |
| Example 4 | | | |

(*) D2 means value of washed powder.

1. A surface-treated inorganic powder, which satisfies the following expression (1) and the following expression (2):
3.0≤D1≤50.0 Expression (1)
1.00≤D1/D2<1.10 Expression (2)
in the expression (1) and the expression (2), D1 represents a presence amount (μmol/m²) of double bonds contained in the surface-treated inorganic powder, and D2 represents a presence amount (μmol/m²) of double bonds contained in a washed powder, wherein the washed powder is a powder obtained by sequentially subjecting the surface-treated inorganic powder to treatments shown in the following <1> to <3>:
<1> 50 mL of methanol and 10 g of the surface-treated inorganic powder are mixed to provide a dispersion liquid;
<2> the dispersion liquid is treated with an ultrasonic disperser at an output of 40 W for 20 minutes to provide a slurry; and
<3> solid matter obtained by centrifuging the slurry and removing a supernatant is dried under reduced pressure at a pressure of 0.1 MPa and a temperature of 50° C. for a treatment time of 12 hours to provide the washed powder.

2. The surface-treated inorganic powder according to claim 1, wherein the surface-treated inorganic powder comprises:
an inorganic powder; and
a surface treatment agent, which is present on a surface of the inorganic powder, and contains a carbon atom.

3. The surface-treated inorganic powder according to claim 2, wherein the surface treatment agent comprises a silane coupling agent having a (meth)acryloyl group.

4. The surface-treated inorganic powder according to claim 3, wherein the silane coupling agent having a (meth)acryloyl group is an aliphatic silane coupling agent having a (meth)acryloyl group.

5. The surface-treated inorganic powder according to claim 1, wherein the surface-treated inorganic powder has a carbon content per unit surface area within a range of from 10 μmol/m² to 200 μmol/m².

6. The surface-treated inorganic powder according to claim 5, wherein a difference (C1-C2) between a carbon amount C1 (ppm) of the surface-treated inorganic powder and a carbon amount C2 (ppm) of the washed powder is less than 100 ppm.

7. The surface-treated inorganic powder according to claim 1, wherein, in a ¹³C CP MAS NMR spectrum of the surface-treated inorganic powder, an intensity ratio (M/N) between a peak height (M) within a range of from 120 ppm to 150 ppm and a peak height (N) within a range of from 0 ppm to +10 ppm falls within a range of from 0.5 to 5.

8. The surface-treated inorganic powder according to claim 1, wherein the surface-treated inorganic powder has a sphericity of primary particles of 0.80 or more.

9. The surface-treated inorganic powder according to claim 1, wherein the inorganic powder contains silica.

10. The surface-treated inorganic powder according to claim 1,
wherein the inorganic powder contains a composite oxide containing:
a first component formed of silica; and
a second component formed of at least one kind selected from the group consisting of: titania; zirconia; and alumina, and
wherein a content ratio of the first component in the composite oxide is 60 mol % or more and less than 100 mol %.

11. The surface-treated inorganic powder according to claim 1, wherein a content of coarse particles each having a particle diameter 5 or more times as large as an average particle diameter of the surface-treated inorganic powder is less than 10 ppm.

12. The surface-treated inorganic powder according to claim 1, wherein the surface-treated inorganic powder further comprises less than 50 ppm of a polymerization inhibitor.

13. A method of producing a surface-treated inorganic powder, comprising:
a raw-material-for-surface-treatment preparation step of mixing: 100 parts by mass of a silane coupling agent having a (meth)acryloyl group; 0.3 part by mass to 50 parts by mass of a polymerization inhibitor; and an inorganic powder, to thereby prepare a raw material for surface treatment;
a surface treatment step of heating the raw material for surface treatment to 110° C. or more by a dry process, to thereby prepare a surface-treated raw material containing the inorganic powder surface-treated with the silane coupling agent; and
a washing step of washing the surface-treated raw material.

14. A dispersion, comprising a surface-treated inorganic powder,
wherein the surface-treated inorganic powder, which satisfies the following expression (1) and the following expression (2):
3.0≤D1≤50.0 Expression (1)
1.00≤D1/D2<1.10 Expression (2)
in the expression (1) and the expression (2), D1 represents a presence amount (μmol/m²) of double bonds contained in the surface-treated inorganic powder, and D2 represents a presence amount (μmol/m²) of double bonds contained in a washed powder, wherein the washed powder is a powder obtained by sequentially subjecting the surface-treated inorganic powder to treatments shown in the following <1> to <3>:
<1> 50 mL of methanol and 10 g of the surface-treated inorganic powder are mixed to provide a dispersion liquid;
<2> the dispersion liquid is treated with an ultrasonic disperser at an output of 40 W for 20 minutes to provide a slurry; and
<3> solid matter obtained by centrifuging the slurry and removing a supernatant is dried under reduced pressure at a pressure of 0.1 MPa and a temperature of 50° C. for a treatment time of 12 hours to provide the washed powder.

15. A resin composition, comprising a surface-treated inorganic powder of,
wherein the surface-treated inorganic powder, which satisfies the following expression (1) and the following expression (2):
3.0≤D1≤50.0 Expression (1)
1.00≤D1/D2<1.10 Expression (2)
in the expression (1) and the expression (2), D1 represents a presence amount (μmol/m²) of double bonds contained in the surface-treated inorganic powder, and D2 represents a presence amount (μmol/m²) of double bonds contained in a washed powder, wherein the washed powder is a powder obtained by sequentially subjecting the surface-treated inorganic powder to treatments shown in the following <1> to <3>:
<1> 50 mL of methanol and 10 g of the surface-treated inorganic powder are mixed to provide a dispersion liquid;
<2> the dispersion liquid is treated with an ultrasonic disperser at an output of 40 W for 20 minutes to provide a slurry; and
<3> solid matter obtained by centrifuging the slurry and removing a supernatant is dried under reduced pressure at a pressure of 0.1 MPa and a temperature of 50° C. for a treatment time of 12 hours to provide the washed powder.
